(19) United States
(12) Patent Application Publication
(10) Pub. No.: US 2010/0277036 A1
(43) Pub. Date: Nov. 4, 2010

(54) BOUNDARY ACOUSTIC WAVE DEVICE

(75) Inventors: Atsushi SHIMIZU, Yasu-shi (JP); Daisuke TAMAZAKI, Joyo-shi (JP); Shinya JOHNOSONO, Hakusan-shi (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi (JP)

(21) Appl. No.: 12/841,324

(22) Filed: Jul. 22, 2010

Related U.S. Application Data
(63) Continuation of application No. PCT/JP2009/000255, filed on Jan. 23, 2009.

(30) Foreign Application Priority Data
Feb. 5, 2008 (JP) 2008-025344

(51) Int. Cl. H01L 41/04; H01L 41/047; H01L 41/08

(52) U.S. Cl. 310/313 B

(57) ABSTRACT

A boundary acoustic wave device with increased surge withstand voltage includes a dielectric film composed of a first dielectric and disposed on a top surface of a piezoelectric substrate; an electrode including an IDT electrode disposed on the dielectric film; and a dielectric layer composed of a second dielectric arranged so as to cover the electrode.

### BACKGROUND OF THE INVENTION

1. Field of the Invention

The present invention relates to a boundary acoustic wave device in which an electrode is provided at an interface between a piezoelectric and a dielectric. Specifically, the present invention relates to a boundary acoustic wave device having an improved multilayer structure.

2. Description of the Related Art

In recent years, boundary acoustic wave devices have been attracting attention as an alternative to surface acoustic wave devices. Since boundary acoustic wave devices do not require hollow packages, boundary acoustic wave devices can be reduced in size.

Japanese Unexamined Patent Application Publication No. 2006-319887 discloses a boundary acoustic wave device in which a first medium made of LiNbO₃ or other suitable material and a second medium made of SiO₂ or other suitable material are stacked and an IDT electrode is provided between the first and second media. The IDT electrode is subjected to apodization weighting and the gap width between an electrode finger and a dummy electrode finger is set within a certain range. As a result, degradation of characteristics caused by the diffraction phenomenon of boundary acoustic waves is suppressed.

However, when existing boundary acoustic wave devices, such as that described in Japanese Unexamined Patent Application Publication No. 2006-319887, are subjected to a surge withstand voltage test, there are cases in which electrode breakdown occurs under a relatively low voltage.

In addition, as with surface acoustic wave devices, a decrease in insertion loss has also been strongly demanded in boundary acoustic wave devices.

### SUMMARY OF THE INVENTION

To overcome the problems described above, preferred embodiments of the present invention provide a boundary acoustic wave device in which the surge withstand voltage can be increased and provide a boundary acoustic wave device in which the surge withstand voltage is high and the insertion loss is low.

A preferred embodiment of the present invention provides a boundary acoustic wave device including a piezoelectric substrate including a top surface, a dielectric film provided on the top surface of the piezoelectric substrate and that is made of a first dielectric, an electrode that is provided on the dielectric film and at least includes an interdigital transducer (IDT) electrode, and a dielectric layer that is arranged so as to cover the electrode and that is made of a second dielectric. Surge withstand voltage is increased due to the IDT electrode being provided on the dielectric film made of the first dielectric, the dielectric film being provided on the top surface of the piezoelectric substrate.

A dielectric material for forming the first dielectric is not particularly restricted. According to a preferred embodiment of the present invention, the first dielectric preferably is a dielectric selected from the group consisting of

Ta₂O₅, TiO₂, TiO, SiO₂, MgO, Al₂O₃, Nb₂O₅, Cr₂O₃, ZrO₂, ZnO, NiO, WO₃, HfO₂, AlN, TiN, Si₃N₄, and SiC. In this case, the surge withstand voltage can be more effectively increased. In particular, 1a₂O₅ is preferably used as the first dielectric and the surge withstand voltage can be more effectively increased.

According to another preferred embodiment of the present invention, the dielectric film made of the first dielectric preferably has a thickness of about 0.018λ or less where λ represents a wavelength of boundary acoustic waves used. In this case, the loss of the boundary acoustic wave device can be reduced.

In a boundary acoustic wave device according to a preferred embodiment of the present invention, the dielectric film made of the first dielectric is preferably located, on the top surface of the piezoelectric substrate, at least in a region where the electrode is located.

The dielectric film is preferably disposed over the entirety of the top surface of the piezoelectric substrate. In this case, the dielectric film made of the first dielectric can be readily formed without patterning or the like.

According to another preferred embodiment of the present invention, a second dielectric layer made of a third dielectric is further provided. The second dielectric layer made of the third dielectric is preferably stacked on the dielectric layer made of the second dielectric, and an acoustic velocity of the third dielectric is larger than an acoustic velocity of the second dielectric.

As for a material for forming the piezoelectric substrate, various piezoelectric materials may be used; however, a preferred material is LiNbO₃. As a result, by forming a dielectric film made of a first dielectric according to a preferred embodiment of the present invention, the surge withstand voltage can be effectively increased.

In a boundary acoustic wave device according to a preferred embodiment of the present invention, since a dielectric film made of a first dielectric is disposed on a piezoelectric substrate and an electrode including an IDT electrode is disposed on the dielectric film, surge withstand voltage can be increased compared with existing boundary acoustic wave devices. Accordingly, boundary acoustic wave devices can be made more reliable.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic front sectional view for illustrating a boundary acoustic wave device according to a first preferred embodiment of the present invention.

FIG. 2 is a schematic plan view illustrating the electrode structure of the boundary acoustic wave device illustrated in FIG. 1.

FIG. 3 is a partial enlarged front sectional view for illustrating the electrode multilayer structure of the boundary acoustic wave device according to the first preferred embodiment illustrated in FIG. 1.

FIG. 4 is a schematic front sectional view for illustrating a modification of a boundary acoustic wave device in which a second dielectric layer is stacked between a dielectric layer and a protective film.

FIG. 5 is a graph illustrating variation in voltage at which insertion loss in a band has been degraded by about 0.3 dB, that is, variation in surge withstand voltage, when duty ratios are changed in a boundary acoustic wave device illustrated in FIGS. 1 and 2 according to the first preferred embodiment, a boundary acoustic wave device in which boundary acoustic wave resonator sections are not formed according to a second preferred embodiment, and a boundary acoustic wave device of a comparative example.

FIG. 6 is a graph illustrating a filter characteristic of a boundary acoustic wave device of the comparative example and boundary acoustic wave devices in which dielectrics made of Ta₂O₅ have different thicknesses according to a plurality of preferred embodiments of the present invention.

FIG. 7 is a graph illustrating the filter characteristic of the boundary acoustic wave device of the comparative example, the filter characteristic being represented by a solid line A in FIG. 6.

FIG. 8 is a graph illustrating the filter characteristic of the boundary acoustic wave device of a preferred embodiment of the present invention, the filter characteristic being represented by a broken line B in FIG. 6.

FIG. 9 is a graph illustrating the filter characteristic of the boundary acoustic wave device of a preferred embodiment of the present invention, the filter characteristic being represented by an alternating long and short dashed line C in FIG. 6.

FIG. 10 is a graph illustrating the filter characteristic of the boundary acoustic wave device of a preferred embodiment of the present invention, the filter characteristic being represented by a narrow line D in FIG. 6.

FIG. 11 is a graph illustrating variation in insertion loss when the normalized thickness of a Ta₂O₅ film serving as a dielectric film is changed.

### DETAILED DESCRIPTION OF THE PREFERRED EMBODIMENTS

Hereinafter, the present invention will be disclosed by describing specific preferred embodiments of the present invention with reference to drawings.

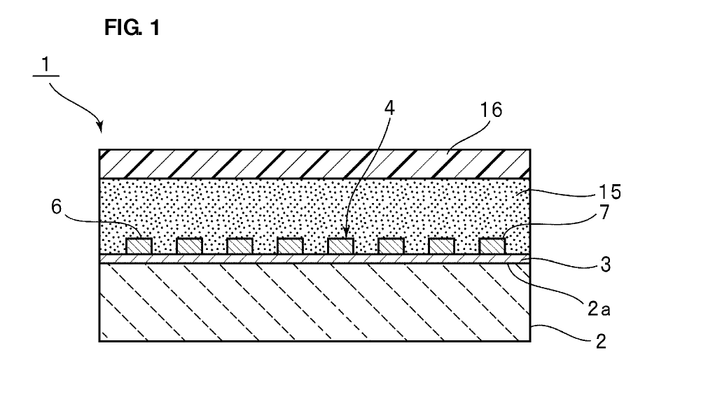

FIG. 1 is a schematic sectional front view of a boundary acoustic wave device according to a first preferred embodiment of the present invention. A boundary acoustic wave device 1 includes a piezoelectric substrate 2. The piezoelectric substrate 2, which is made of an appropriate piezoelectric, preferably is a 15° Y cut X propagation LiNbO₃ substrate in the first preferred embodiment. Alternatively, a LiNbO₃ substrate having another crystal orientation may also be used. Alternatively, another piezoelectric single crystal substrate made of LiTaO₃, quartz, or the like; or a piezoelectric substrate made of a piezoelectric ceramic such as a lead zirconate titanate ceramic may also be used.

A dielectric film 3 made of Ta₂O₅ serving as a first dielectric is disposed on a top surface 2a of the piezoelectric substrate 2. The first dielectric is not particularly restricted and an appropriate dielectric material with which surge withstand voltage described below can be increased can be used. Such a dielectric is preferably selected from the group consisting of Ta₂O₅, TiO₂, TiO, SiO₂, MgO, Al₂O₃, Nb₂O₅, Cr₂O₃, ZrO₂, ZnO, NiO, WO₃, HfO₂, AlN, TiN, Si₃N₄, and SiC. More preferably, since the surge withstand voltage can be effectively increased, Ta₂O₅ is used.

In the first preferred embodiment, the dielectric film 3 is preferably disposed over the entirety of the top surface 2a of the piezoelectric substrate 2. Alternatively, the dielectric film 3 may be disposed on a portion of the top surface 2a of the piezoelectric substrate 2. That is, the dielectric film 3 should be present at least under a portion in which an electrode 4 described below is formed. Stated another way, the dielectric film 3 is preferably disposed at least in a region where the electrode 4 is located, in the top surface 2a of the piezoelectric substrate 2.

In the boundary acoustic wave device 1, by providing the dielectric film 3, the surge withstand voltage can be effectively increased as will be demonstrated in experimental examples described below. This is probably achieved because insulation resistance (IR) is increased.

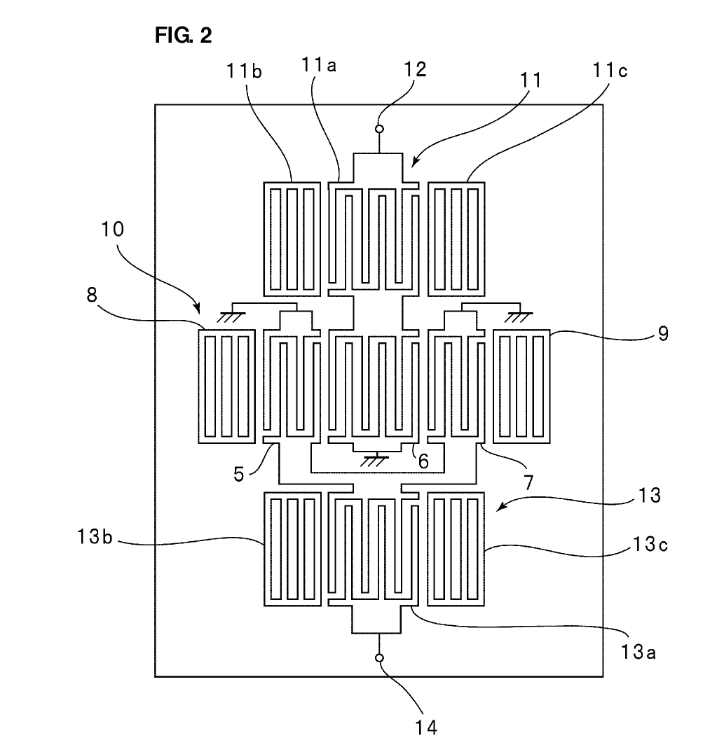

The electrode 4 is disposed on the dielectric film 3. The planar configuration of the electrode 4 is schematically illustrated in FIG. 2. Although the electrode 4 is simply illustrated in FIG. 1, the electrode 4 has the planar configuration illustrated in FIG. 2. That is, the electrode 4 includes first to third IDT electrodes 5 to 7 that are arranged in a propagation direction of boundary acoustic waves and reflectors 8 and 9 that are arranged in the propagation direction of boundary acoustic waves so as to sandwich a region where the IDT electrodes 5 to 7 are disposed. The first to third IDT electrodes 5 to 7 and the reflectors 8 and 9 constitute a three-IDT resonator boundary acoustic wave filter section 10.

A first single-port boundary acoustic wave resonator section 11 is connected to one end of the second IDT 6 of the boundary acoustic wave filter section 10. The boundary acoustic wave resonator section 11 includes an IDT electrode 11a and reflectors 11b and 11c. One end of the IDT electrode 11a is connected to the second IDT electrode 6 and the other end of the IDT electrode 11a is connected to an input terminal 12. First ends of the first and third IDT electrodes 5 and 7 are connected together to one end of an IDT electrode 13a of a second single-port boundary acoustic wave resonator section 13. A second end of the IDT electrode 13a is connected to an output terminal 14. In the boundary acoustic wave resonator section 13, reflectors 13b and 13c are also arranged in the propagation direction of boundary waves so as to sandwich the IDT electrode 13a.

Note that, in the first preferred embodiment, a boundary acoustic wave filter device is constituted in which the single-port boundary acoustic wave resonator sections 11 and 13 are connected to upstream and downstream portions of the three-IDT boundary acoustic wave filter section 10. However, in a preferred embodiment of the present invention, the structure of an electrode including an IDT electrode is not restricted to that of the electrode 4 of the first preferred embodiment and electrode structures constituting various resonators and band filters can be employed. Note that, although the dielectric film 3 is preferably disposed over the entirety of the top surface 2a of the piezoelectric substrate 2 as described above, the dielectric film 3 will suffice as long as the dielectric film 3 is located, on the top surface of the piezoelectric substrate, at least in a region where such an electrode is located as described above.

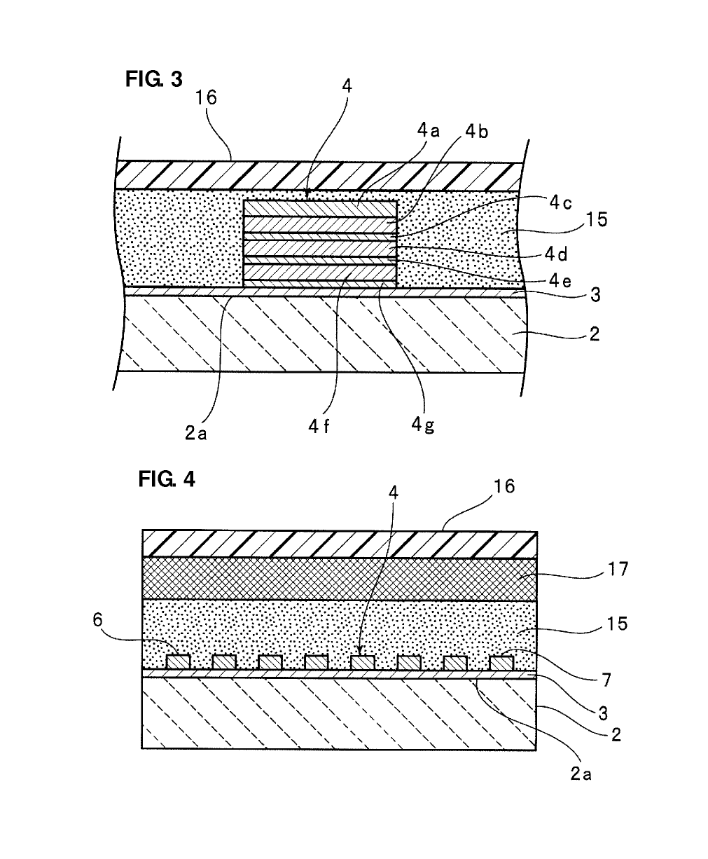

In the first preferred embodiment, the electrode 4 is preferably constituted by a multilayer metal film formed by stacking a plurality of metal films. Alternatively, the electrode 4 may also be constituted by a single metal film. A metal material for forming the electrode is not particularly restricted and a metal such as Cu, Al, Pt, Au, or Ni or an alloy of the foregoing may be appropriately employed. Specifically, as illustrated in FIG. 3 with a schematic enlarged sectional view, the electrode 4 has a structure in which, from above, a NiCr film 4a, a Pt film 4b, a Ti film 4c, an AlCu film 4d, a Ti film 4e, a Pt film 4f, and a Ti film 4g are sequentially stacked. Here, the Ti film 4g, which is a lowermost film, is formed as an adhesion layer for enhancing adhesion to the dielectric film 3. The Ti film 4c and the Ti film 4e are preferably formed to define adhesion layers to enhance the adhesion between the metal films sandwiching these Ti films. The Ti film 4c and the Ti film 4e also function as diffusion suppressing layers between the metal film 4b and the metal film 4d and between the metal film 4d and the metal film 4f. The NiCr film 4a has functions of a protective film to protect the Pt film 4b serving as one of main electrode layers, an adhesion layer to SiO₂, and a frequency adjusting layer. Accordingly, the thicknesses of the NiCr film 4a, the Ti film 4c, the Ti film 4e, and the Ti film 4g are made smaller than the thicknesses of the Pt film 4b, the AlCu film 4d, and the Pt film 4f that serve as main electrode layers.

In addition, in the first preferred embodiment, a dielectric layer 15 made of SiO₂ serving as a second dielectric is stacked so as to cover the electrode 4. A material for forming the dielectric layer 15 is not restricted to SiO₂ and various dielectrics can be used. Other than SiO₂, the second dielectric for forming the dielectric layer 15 may be ZnO, Si₃N₄, AlN, Ta₂O₅, Al₂O₃, B₂O₃, or the like. Note that, the first dielectric and the second dielectric may be the same material or different from each other.

When the first and second dielectrics are the same material, the dielectric film 3 and the dielectric layer 15 of the boundary acoustic wave device 1 can be formed of the same dielectric material. Accordingly, the material cost can be reduced and the production process can be simplified.

However, when appropriate dielectric materials are individually used as the first dielectric and the second dielectric, the surge withstand voltage of the boundary acoustic wave device 1 can be increased while filter characteristics of the boundary acoustic wave device 1 can be readily optimized.

The thickness of the electrode 4 varies depending on a metal material used and the structure of the electrode 4; however, the thickness is generally about 0.01λ to about 0.25λ, for example. To efficiently use boundary acoustic waves, the thickness of the dielectric layer 15 is generally made about 0.4λ to about 3.0λ, for example. However, the thickness of the dielectric layer 15 is also not restricted to this range.

The thickness of the dielectric film 3 is not particularly restricted as long as the dielectric film 3 can provide the effect of increasing the surge withstand voltage described below. However, to reduce insertion loss, the thickness of the dielectric film 3 is desirably made about 0.018λ or less, for example, where X represents the wavelength of boundary acoustic waves used. In this case, the loss can be reduced.

In the first preferred embodiment, a protective layer 16 made of polyimide is further stacked on the top surface of the dielectric layer 15. As a result of the formation of the protective layer 16 made of polyimide, the top surface of the dielectric layer 15 can be protected.

A material for forming the protective layer is not restricted to polyimide and the material may be a synthetic resin such as an epoxy resin, a phenolic resin, an acrylate resin, a urethane resin, a silicone resin, or a polyester; or an inorganic material such as Si₃N₄, AlN, or glass.

In addition, in a preferred embodiment of the present invention, a dielectric layer 17 made of a third dielectric having a larger acoustic velocity than the second dielectric defining the dielectric layer 15 may be disposed between the protective layer 16 made of polyimide and the dielectric layer 15. In this case, electric power handling capability can be effectively enhanced. As for a material for forming the third dielectric, a dielectric material that is different from the second dielectric and is appropriately selected from the group consisting of SiO₂, SiN, AIN, SiC, Al₂O₃, diamond like carbon (DLC), and diamond can be used. That is, a combination of dielectric materials forming the second and third dielectrics can be selected from these dielectric materials.

Use of a combination of the second dielectric being SiO₂ and the third dielectric being SiN is preferred. In this case, the surge withstand voltage handling capability can be more effectively enhanced.

Hereinafter, the fact that the surge withstand voltage is increased and the insertion loss is reduced in the boundary acoustic wave device 1 of the first preferred embodiment will be described on the basis of specific non-limiting experimental examples of various preferred embodiments of the present invention.

In the boundary acoustic wave device 1, the layers of the electrode 4 were made to have the following thicknesses: NiCr/Pt/Ti/AlCu/Ti/Pt/Ti=10/56/10/130/10/56/10 (nm). Each unit of the thicknesses of the layers is nm.

The dielectric film 3 made of Ta₂O₅ was made to have a thickness of about 30 nm. The dielectric layer 15 made of SiO₂ was made to have a thickness of about 4900 μm. The protective layer 16 made of polyimide was made to have a thickness of about 6 μm. The piezoelectric substrate 2 made of LiNbO₃ was made to have a thickness of about 100 μm.

All the duty ratios were made to be about 0.5 in the first to third IDT electrodes 5 to 7, the reflectors 8 and 9, the IDT electrodes 11a and 13a, and the reflectors 11b, 11c, 13b, and 13c. The IDT electrodes 5 to 7 were normal IDT electrodes and the intersecting width of the electrode fingers thereof were made to be about 50.2 μm.

The number of pairs of electrode fingers in the IDT electrodes 5 to 7 was respectively made, from the IDT electrode 5, the IDT electrode 6, to the IDT electrode 7, 8.5, 22, and 8.5. The number of pairs of electrode fingers in the IDT electrode 11a of the boundary acoustic wave resonator section 11 was made 80. The number of pairs of electrode fingers in the IDT electrode 13a of the boundary acoustic wave resonator section 13 was made to be 150.

The thus-produced boundary acoustic wave device 1 was measured in terms of filter characteristic and also subjected to a surge withstand voltage test according to EIA/JESD22-A115-A (Machine Model) defined in EIA/JEDEC STANDARD in the following manner.

Details of the surge withstand voltage test: an equivalent circuit model defined in the above-described standard was prepared and voltages were sequentially applied to the model.

For comparison, a boundary acoustic wave device of a comparative example was also evaluated in terms of filter characteristic and surge withstand voltage in the same manner, the boundary acoustic wave device having the same configuration as in the first preferred embodiment except that the dielectric film 3 made of Ta₂O₅ was not formed. In addition, a boundary acoustic wave device according to a second preferred embodiment was also evaluated in terms of surge withstand voltage in the same manner, the boundary acoustic wave device being formed as in the first preferred embodiment except that the first and second boundary acoustic wave resonator sections 11 and 13 were not formed.

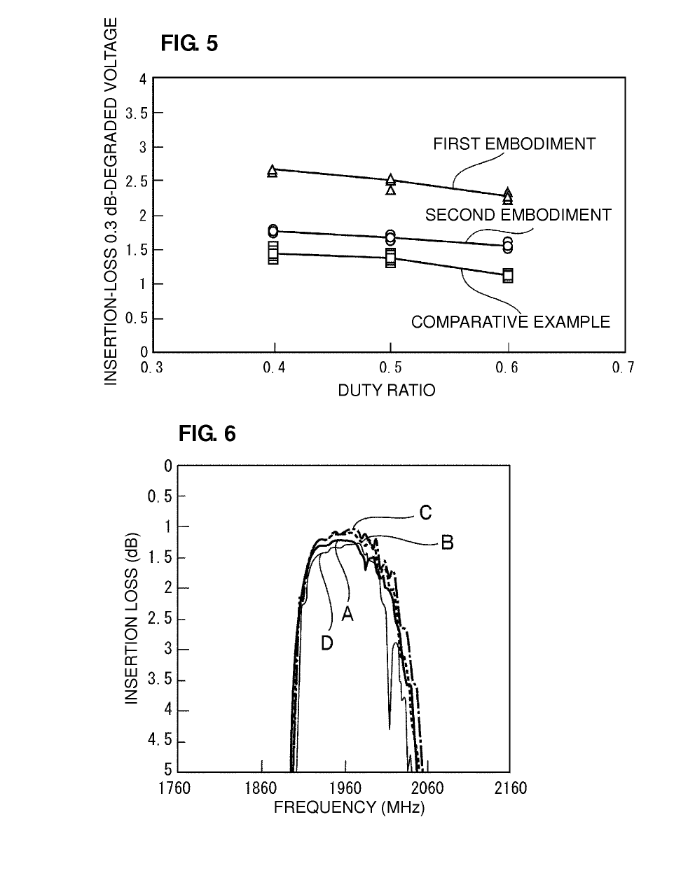

The results of the surge withstand voltage tests are shown in Table 1 below and FIG. 5. Note that the 0.3 dB-degraded voltage values in Table 1 and FIG. 5 each represent the value of an applied voltage at which the minimum insertion loss in the pass band had been degraded by 0.3 dB. The rows of electrode breakdown voltage in Table 1 show applied voltages at which breakdown of electrodes such as IDT electrodes had occurred. In Table 1, test results of four samples are shown for both the first preferred embodiment and the comparative example.

Table 1 also shows values of insulation resistance (IR) of the boundary acoustic wave devices of the example and the comparative example.

FIG. 5 illustrates variation in the 0.3 dB-degraded voltage of the three boundary acoustic wave devices when the duty ratios of the IDT electrodes 5 to 7 were changed.

TABLE 1

| | | | Sample No. | | | | | |
|---|---|---|---|---|---|---|---|---|
| | Ta₂O₅ | Criteria | 1 | 2 | 3 | 4 | Average | IR (Ω) |
| First | Present | 0.3 dB-degraded voltage | 2.39 | 2.28 | 2.34 | 2.34 | 2.34 | 10¹⁰ |
| embodiment | | Electrode breakdown voltage | 3.12 | 3.04 | 2.45 | 2.76 | 2.84 | |
| Comparative | Absent | 0.3 dB-degraded voltage | * | * | * | * | * | 10⁶ |
| example | | Electrode breakdown voltage | 1.04 | 0.85 | 1.11 | 1.00 | 1.00 | |

The 0.3 dB-degraded voltage and the electrode breakdown voltage in Table 1 are represented as proportions with respect to the average value of the electrode breakdown voltages of the comparative example.

Table 1 and FIG. 5 show the surge withstand voltages of the first preferred embodiment and the comparative example when the average value of the electrode breakdown voltages in the surge withstand voltage of the comparative example is defined as 1. As is evident from Table 1, in the first preferred embodiment, the voltages at which electrode breakdown occurred were about 2.45 or more and about 2.84 on average, which is high. In addition, the voltages at which the insertion loss in the pass band had been degraded by 0.3 dB were about 2.28 or more, which is high. This shows that, even when a high voltage of about 2.25 was applied, the insertion loss was only slightly degraded.

In addition, as is evident from FIG. 5, regardless of the values of the duty, in the second preferred embodiment in which the boundary acoustic wave resonator sections 11 and 13 were not formed, the voltages at which the insertion loss in the pass band had been degraded by 0.3 dB were about 1.5 or more.

Accordingly, this shows that, regardless of the presence or absence of the boundary acoustic wave resonator sections 11 and 13, the surge withstand voltage can be effectively increased by disposing the dielectric film 3 between the top surface 2a of the piezoelectric substrate 2 and the electrode 4 according to a preferred embodiment of the present invention.

FIG. 6 is a graph illustrating an attenuation frequency characteristic of the boundary acoustic wave device of the comparative example and three boundary acoustic wave devices in which the thickness of the Ta₂O₅ was made different from that of the preferred embodiments of the present invention. Note that, since the dielectric film 3 was not disposed in the comparative example, the film thickness of Ta₂O₅ was 0 nm. In FIG. 6, the solid line A represents the result of the comparative example. The result of the case where the dielectric film 3 made of Ta₂O₅ had a thickness of about 12.6 nm is represented by the broken line B. The result of the case where the dielectric film 3 made of Ta₂O₅ had a thickness of about 18 nm, the case corresponding to the first preferred embodiment, is represented by the alternating long and short dashed line C. Furthermore, the result of the case where the dielectric film 3 made of Ta₂O₅ had a thickness of about 32.6 nm is represented by the narrow line D.

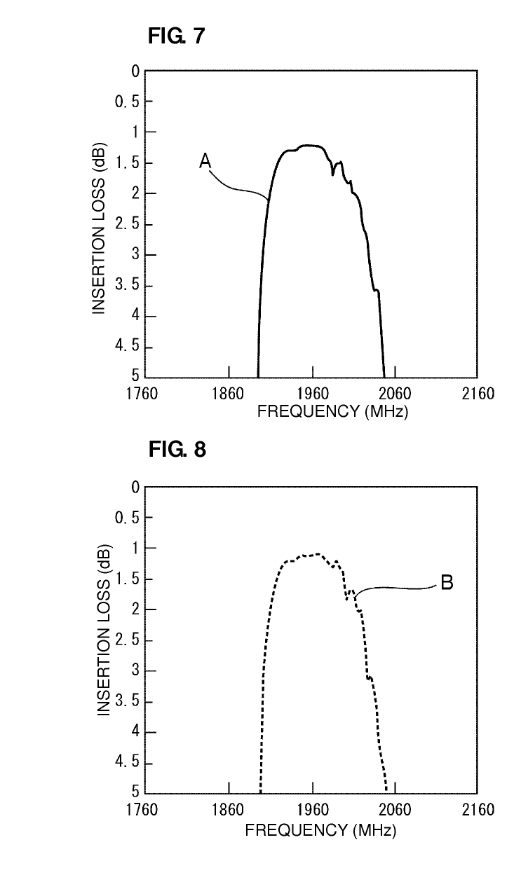

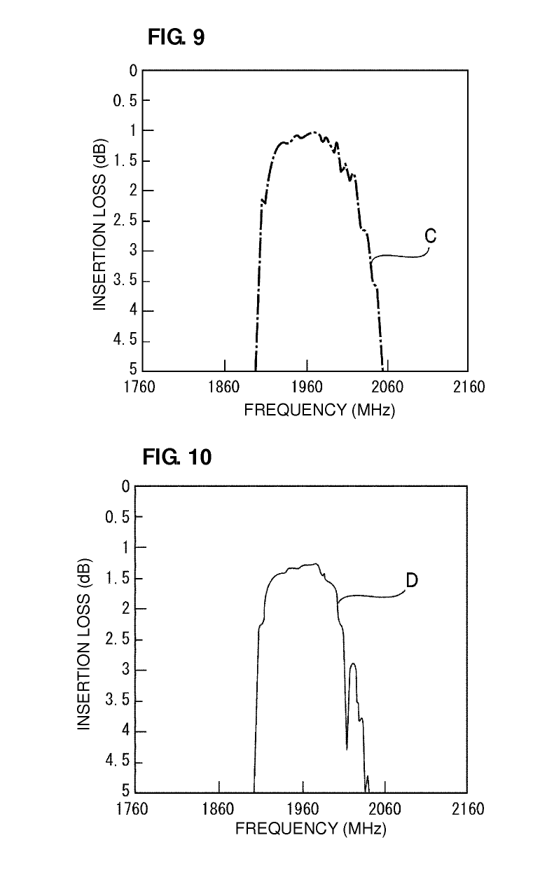

However, these lines are mixed up in FIG. 6 and the difference between the lines is difficult to see. Accordingly, the filter characteristics represented by the solid line A, the broken line B, the alternating long and short dashed line C, and the narrow line D are independently illustrated in FIGS. 7 to 10.

As is evident from FIGS. 6 to 10, the insertion loss in the pass band varies with the thickness of the dielectric film 3 made of Ta₂O₅.

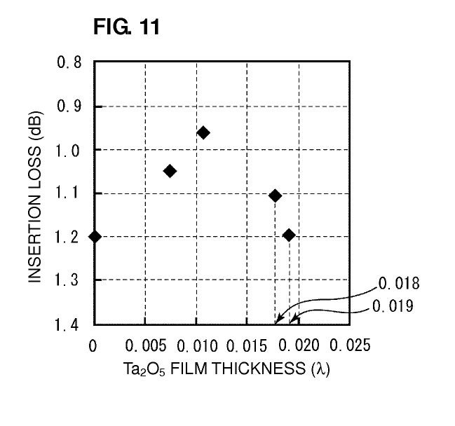

Accordingly, a plurality of boundary acoustic wave devices in which normalized Ta₂O₅ film thicknesses, that is, the film thicknesses of the dielectric films 3 made of Ta₂O₅, the film thicknesses being normalized with the wavelength λ of boundary acoustic waves, were varied, were measured in terms of filter characteristic and the relationship between the minimum insertion loss in the pass band and the Ta₂O₅ film thicknesses normalized with the wavelength λ of boundary acoustic waves was determined. The results are shown in Table 2 and FIG. 11.

TABLE 2

| | Insertion loss |
|---|---|
| Ta₂O₅ film thickness | (dB) |
| 0.000λ | 1.20 |
| 0.007λ | 1.05 |
| 0.011λ | 0.96 |
| 0.018λ | 1.11 |
| 0.019λ | 1.20 |

As is evident from Table 2 and FIG. 11, the minimum insertion loss in the pass band decreases as the Ta₂O₅ film thickness increases from 0; however, as the film thickness increases from about 0.011λ, the insertion loss increases back. However, it has been demonstrated that, when the Ta₂O₅ normalized film thickness is about 0.018λ or less, the insertion loss can be made smaller than about 1.2 dB, which is the insertion loss of the comparative example. Accordingly, the film thickness of the dielectric film 3 made of Ta₂O₅ is preferably made 0.018λ or less. As a result, the insertion loss can be reduced.

Although the results of cases where the dielectric films 3 were made of Ta₂O₅ were shown in the experimental examples, similar results are also obtained when the above-described other dielectric materials are used. That is, when another dielectric material is used, by making the normalized film thickness about 0.018λ or less, the insertion loss can be similarly reduced.

The present invention is not restricted to the above-described boundary acoustic wave filter devices. The present invention is also applicable to boundary acoustic wave resonators. In this case, Q of boundary acoustic wave resonators is enhanced and the loss is similarly reduced. Therefore, according to the present invention, the loss can be reduced by forming the dielectric film 3.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A boundary acoustic wave device comprising:
a piezoelectric substrate including a top surface;
a dielectric film disposed on the top surface of the piezoelectric substrate and made of a first dielectric;
an electrode disposed on the dielectric film and at least including an IDT electrode; and
a dielectric layer arranged so as to cover the electrode and made of a second dielectric.

2. The boundary acoustic wave device according to claim 1, wherein the first dielectric is a dielectric selected from the group consisting of Ta₂O₅, TiO₂, TiO, SiO₂, MgO, Al₂O₃, Nb₂O₅, Cr₂O₃, ZrO₂, ZnO, NiO, WO₃, HfO₂, AlN, TiN, Si₃N₄, and SiC.

3. The boundary acoustic wave device according to claim 2, wherein the first dielectric is Ta₂O₅.

4. The boundary acoustic wave device according to claim 1, wherein the dielectric film made of the first dielectric has a thickness of about 0.018λ or less where λ represents a wavelength of boundary acoustic waves used.

5. The boundary acoustic wave device according to claim 1, wherein the dielectric film made of the first dielectric is disposed, on the top surface of the piezoelectric substrate, at least in a region where the electrode is located.

6. The boundary acoustic wave device according to claim 5, wherein the dielectric film made of the first dielectric is arranged over an entirety of the top surface of the piezoelectric substrate.

7. The boundary acoustic wave device according to claim 1, further comprising a second dielectric layer made of a third dielectric, wherein the second dielectric layer made of the third dielectric is stacked on the dielectric layer made of the second dielectric; and an acoustic velocity of the third dielectric is larger than an acoustic velocity of the second dielectric.

8. The boundary acoustic wave device according to claim 1, wherein the piezoelectric substrate is made of LiNbO₃.
